(19) United States
(12) Patent Application Publication
(10) Pub. No.: US 2013/0300639 A1
(43) Pub. Date: Nov. 14, 2013

(54) ORGANIC LIGHT EMITTING DISPLAY DEVICE AND METHOD OF DRIVING THE SAME

(71) Applicant: Dong-Hwi Kim, Yongin-city (KR)

(72) Inventor: Dong-Hwi Kim, Yongin-city (KR)

(21) Appl. No.: 13/587,856

(22) Filed: Aug. 16, 2012

(30) Foreign Application Priority Data
May 10, 2012 (KR) 10-2012-0049722

(51) Int. Cl. G09G 3/32; G09G 5/00; H01L 27/32

(52) U.S. Cl. 345/83; 257/89; 257/40; 257/E27.119

(57) ABSTRACT

An organic light emitting display device including: red sub-pixels, each including a red organic light emitting diode and a driving transistor; green sub-pixels, each including a green organic light emitting diode and a driving transistor; and blue sub-pixels, each including a blue organic light emitting diode and a driving transistor, wherein the driving transistors of the red, green, and blue sub-pixels are configured to be initialized by a voltage applied to an anode electrode of the red, green, or blue organic light emitting diodes.

### CROSS-REFERENCE TO RELATED APPLICATION

This application claims priority to and the benefit of Korean Patent Application No. 10-2012-0049722, filed on May 10, 2012, in the Korean Intellectual Property Office, the entire content of which is incorporated herein by reference.

### BACKGROUND

1. Field

Aspects of the present invention relate generally to an organic light emitting display device and a method of driving the same.

2. Description of the Related Art

Recently, various flat panel display devices capable of reducing weight and volume, which are disadvantages of a cathode ray tube, have been developed. Examples of flat panel display devices include a liquid crystal display, a field emission display, a plasma display panel, an organic light emitting display device, and the like.

Among the flat panel display devices, the organic light emitting display device, which displays an image using organic light emitting diodes that generate light by recombination between electrons and holes, has various advantages, such as a rapid response speed and that it may be driven at a relatively low power.

The organic light emitting display device includes a plurality of sub-pixels arranged in a matrix form. Each sub-pixel is located at a portion at which data lines, scan lines, and power lines cross with each other. The sub-pixels may include, for example, an organic light emitting diode, at least two transistors (including a driving transistor), and at least one capacitor.

The organic light emitting display device, as described above, has a low power consumption. However, an amount of current flowing to the organic light emitting diode varies according to a variation in threshold voltages between the driving transistors included in each of the sub-pixels, which may cause non-uniformity of the display. That is, characteristics of the driving transistor may vary according to manufacturing process variables of the driving transistors provided in each of the sub-pixels. In fact, it is highly unlikely, using current processes, to manufacture the transistors of the organic light emitting display device so that all of the transistors have the same characteristics. Therefore, a variation in threshold voltage between the driving transistors is likely to occur.

In order to address this phenomenon, a compensating circuit, including a plurality of transistors and a capacitor, may be added to each of the sub-pixels. Here, the compensating circuit included in each of the sub-pixels is charged with a voltage corresponding to the threshold voltage of the driving transistor, thereby compensating for the variation between the driving transistors. To this end, each compensating circuit initializes a gate electrode of the driving transistor using an initialization power.

However, when the compensating circuit is provided for initializing the gate electrode of the driving transistor using the initialization power, a power line supplying the initialization power may be formed in each sub-pixel area, which may use additional space. Therefore, it may be difficult to implement a high resolution and yield may be reduced.

### SUMMARY

An aspect of embodiments of the present invention is to provide an organic light emitting display device directed toward increasing a yield and a resolution of the display, and a method of driving the same.

According to an exemplary embodiment of the present invention, there is provided an organic light emitting display device including: red sub-pixels, each including a red organic light emitting diode and a driving transistor; green sub-pixels, each including a green organic light emitting diode and a driving transistor; and blue sub-pixels, each including a blue organic light emitting diode and a driving transistor, wherein the driving transistors of the red, green, and blue sub-pixels are configured to be initialized by a voltage applied to an anode electrode of the red, green, or blue organic light emitting diodes.

The driving transistors may be configured to be initialized by the voltage applied to the anode electrode of the blue organic light emitting diode.

The red, green, and blue sub-pixels that are adjacent to each other may form one of a plurality of pixels, and driving transistors in a same one of the pixels may be configured to be initialized by the voltage applied to the anode electrode of the red, green, or blue organic light emitting diodes in the same one of the pixels.

The driving transistors in the same one of the pixels may be configured to be initialized by the voltage applied to the anode electrode of the blue organic light emitting diode in the same one of the pixels.

Each of the red, green, and blue sub-pixels that is positioned at an i-th (i being a natural number) horizontal line may further include: a second transistor coupled between a gate electrode of the driving transistor and the anode electrode of the blue organic light emitting diode in the same one of the pixels, the second transistor being configured to be turned on when a scan signal is supplied to an (i−1)-th scan line.

Each of the red, green, and blue sub-pixels that is positioned at the i-th (i being a natural number) horizontal line may further include: a third transistor coupled between the gate electrode of the driving transistor and a second electrode of the driving transistor, the third transistor being configured to be turned on when the scan signal is supplied to the i-th scan line; a fourth transistor coupled between a first electrode of the driving transistor and a data line, the fourth transistor being configured to be turned on when the scan signal is supplied to the i-th scan line; a fifth transistor coupled between the first electrode of the driving transistor and a first power supply, the fifth transistor being configured to be turned off when a light emitting control signal is supplied to an i-th light emitting control line; a sixth transistor coupled between the second electrode of the driving transistor and an anode electrode of an organic light emitting diode included therein, the sixth transistor being configured to be turned off when the light emitting control signal is supplied to the i-th light emitting control line; and a storage capacitor coupled between the gate electrode of the driving transistor and the first power supply.

The light emitting control signal is configured to be supplied to the i-th light emitting control line such that it may be overlapped with the scan signals supplied to the (i−1)-th scan line and the i-th scan line.

According to another exemplary embodiment of the present invention, there is provided a method of driving an organic light emitting display device, the method including: initializing a gate electrode of a driving transistor included in each of a plurality of sub-pixels; storing a voltage corresponding to a data signal in each of the sub-pixels; and generating light corresponding to the stored voltage of the data signal in each of the sub-pixels, wherein each of the sub-pixels is initialized by a voltage of an anode electrode of a red organic light emitting diode, a green organic light emitting diode, or a blue organic light emitting diode.

The sub-pixels may be initialized by the voltage of the anode electrode of the blue organic light emitting diode.

In some embodiments, each of the sub-pixels is either a red sub-pixel, a blue sub-pixel, or a green sub-pixel, one of the red sub-pixels, one of the blue sub-pixels, and one of the green sub-pixels that are all arranged adjacent to each other are one pixel of a plurality of pixels, and the red sub-pixel, the blue sub-pixel, and the green sub-pixel of a same one of the pixels are all initialized by the voltage of the anode electrode of the red organic light emitting diode, the green organic light emitting diode, or the blue organic light emitting diode of the same one of the pixels.

The red sub-pixel, the blue sub-pixel, and the green sub-pixel of the same one of the pixels may be initiated by the voltage of the anode electrode of the blue organic light emitting diode of the blue sub-pixel of the same one of the pixels.

### BRIEF DESCRIPTION OF THE DRAWINGS

The accompanying drawings, together with the specification, illustrate aspects of embodiments of the present invention, and, together with the description, serve to explain the principles of the present invention.

FIG. 1 is a diagram showing an organic light emitting display device according to an exemplary embodiment of the present invention;

FIG. 2 is a circuit diagram showing an example of a sub-pixel shown in FIG. 1;

FIG. 3 is a waveform diagram showing a driving waveform supplied to a pixel shown in FIG. 2; and

FIG. 4 is a diagram showing a configuration of the pixel according to an exemplary embodiment of the present invention.

### DETAILED DESCRIPTION

Hereinafter, certain exemplary embodiments according to the present invention will be described with reference to the accompanying drawings. Here, when a first element is described as being coupled (e.g., electrically coupled or connected) to a second element, the first element may not only be directly coupled to the second element but may also be indirectly coupled to the second element via one or more intervening elements. Further, some of the elements that are not essential to the complete understanding of the invention may be omitted for clarity. Also, like reference numerals refer to like elements throughout.

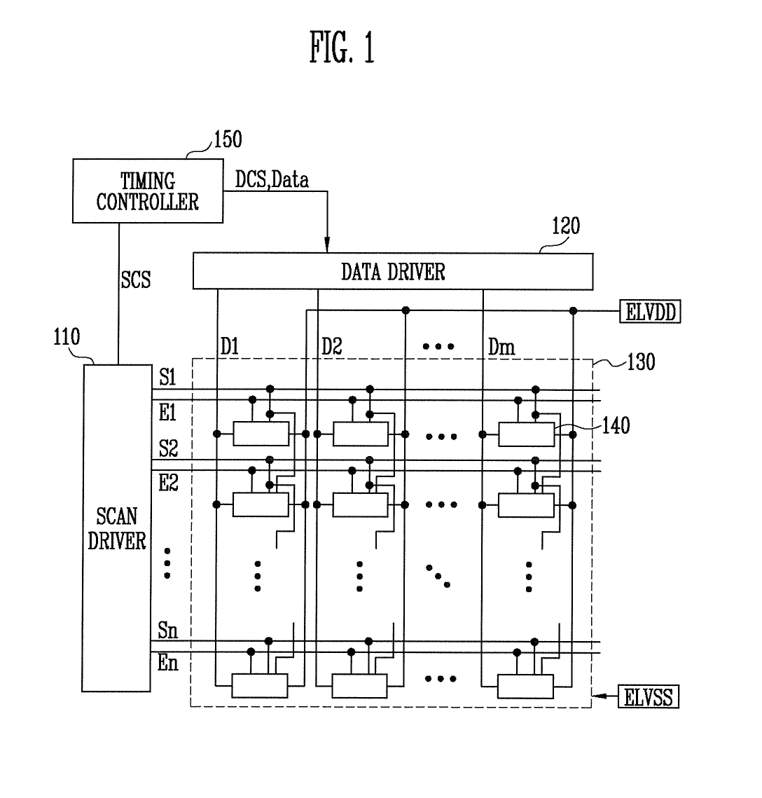

Hereinafter, exemplary embodiments of the present invention are described in detail with reference to FIGS. 1 through 4 so that those skilled in the art may easily practice the present invention.

FIG. 1 is a diagram showing an organic light emitting display device according to an exemplary embodiment of the present invention.

Referring to FIG. 1, the organic light emitting display device according to the exemplary embodiment of the present invention includes a pixel unit 130, including sub-pixels 140, each positioned at portions at which scan lines S1 to Sn and data lines D1 to Dm cross with each other, a scan driver 110 driving the scan lines S1 to Sn and light emitting control lines E1 to En, a data driver 120 driving the data lines D1 to Dm, and a timing controller 150 controlling the scan driver 110 and the data driver 120.

The timing controller 150 may generate data driving control signals DCS and scan driving control signals SCS, which correspond to synchronization signals supplied from outside. The data driving control signals DCS generated in the timing controller 150 may be supplied to the data driver 120, and the scan driving control signals SCS generated therein may be supplied to the scan driver 110. In addition, the timing controller 150 may supply data Data supplied from the outside to the data driver 120.

The scan driver 110 receiving the scan driving control signals SCS may generate scan signals and may sequentially supply the generated scan signals to the scan lines S1 to Sn. In addition, the scan driver 110 may generate light emitting control signals in response to the scan driving control signals SCS and may sequentially supply the generated light emitting control signals to the light emitting control lines E1 to En. Here, a width of the light emitting control signal is set to be the same as or wider than that of the scan signal. For example, a light emitting control signal supplied to an i-th (i being a natural number) light emitting control line Ei may be overlapped with scan signals supplied to (i−1)-th and i-th scan lines Si-1 and Si

The data driving unit 120 receiving the data driving control signals DCS may generate data signals and may supply the generated data signals to the data lines D1 to Dm so as to be synchronized with the scan signals.

In FIG. 1, the pixel unit 130 receives a first power ELVDD and a second power ELVSS from the outside to supply the received powers to each of sub-pixels 140. Each of the sub-pixels 140 receiving the first and second powers ELVDD and ELVSS generates light corresponding to the data signals. Here, sub-pixels 140 positioned on an i-th horizontal line may initialize gate electrodes of the driving transistors during a period in which the scan signal is supplied to an (i−1)-th scan line Si-1, and may be charged with a voltage corresponding to a threshold voltage of the driving transistor and the data signal during a period in which the scan signal is supplied to an i-th scan line Si.

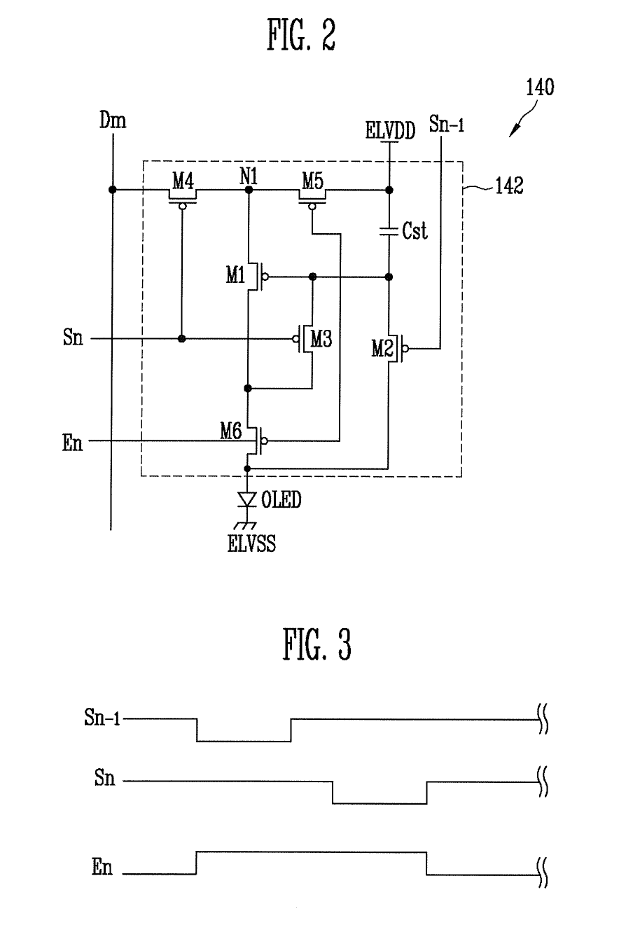

FIG. 2 is a circuit diagram showing an example of a sub-pixel shown in FIG. 1. For convenience of explanation, only a sub-pixel coupled to an m-th data line Dm, an n-th scan line Sn, an (n−1)-th scan line Sn-1, and an n-th light emitting control line En is shown In FIG. 2.

Referring to FIG. 2, a sub-pixel 140 according to an exemplary embodiment of the present invention includes an organic light emitting diode OLED and a pixel circuit 142 coupled to the data line Dm, the scan lines Sn-1 and Sn, and the light emitting control line En to control an amount of current supplied to the organic light emitting diode OLED.

An anode electrode of the organic light emitting diode OLED is coupled to the pixel circuit 142, and a cathode electrode thereof is coupled to the second power supply ELVSS. Here, a voltage value of the second power ELVSS is set to be lower than that of the first power ELVDD. As described above, the organic light emitting diode OLED generates light having a suitable (e.g., a predetermined or set brightness) corresponding to the amount of current supplied from the pixel circuit 142.

The pixel circuit 142 controls the amount of current supplied to the organic light emitting diode OLED, which corresponds to the data signal supplied to the data line Dm, when the scan signal is supplied to the scan line Sn. To this end, the pixel circuit 142 may include first to sixth transistors M1 to M6 and a storage capacitor Cst.

In the pixel circuit 142 according to an exemplary embodiment of the present invention, a first electrode of the fourth transistor M4 is coupled to the data line Dm, and a second electrode thereof is coupled to a first node N1. In addition, a gate electrode of the fourth transistor M4 is coupled to the n-th scan line Sn. The transistor M4, as described above, is turned on when the scan signal is supplied to the n-th scan line Sn, thereby supplying the data signal supplied to the data line Dm to the first node N1.

Additionally, in the pixel circuit 142, a first electrode of the first transistor M1 is coupled to the first node N1, and a second electrode thereof is coupled to a first electrode of the sixth transistor M6. In addition, a gate electrode of the first transistor M1 (i.e., the driving transistor) is coupled to a first terminal (e.g., a one side terminal) of the storage capacitor Cst. The first transistor M1, as described above, supplies a current corresponding to a voltage charged in the storage capacitor Cst to the organic light emitting diode OLED.

As shown in FIG. 2, a first electrode of the third transistor M3 is coupled to the second electrode of the first transistor M1, and a second electrode thereof is coupled to the gate electrode of the first transistor M1. Further, a gate electrode of the third transistor M3 is coupled to the n-th scan line Sn. The third transistor M3, as described above, is turned on when the scan signal is supplied to the n-th scan line, thereby diode-connecting the first transistor M1 to the n-th scan line.

In the pixel circuit 142 of the exemplary embodiment, a gate electrode of the second transistor M2 is coupled to the (n−1)-th scan line Sn-1, and a first electrode thereof is coupled to the first terminal of the storage capacitor Cst and the gate electrode of the first transistor M1. In addition, the second electrode of the second transistor M2 is coupled to the anode electrode of the organic light emitting diode OLED. The second transistor M2, as described above, is turned on when the scan signal is supplied to the (n−1)-th scan line Sn-1, thereby initializing the first terminal of the storage capacitor Cst and the gate electrode of the first transistor M1 by a voltage at the anode electrode of the organic light emitting diode OLED.

As shown in FIG. 2, a first electrode of the fifth transistor M5 is coupled to the first power supply ELVDD, and a second electrode thereof is coupled to the first node N1. Further, a gate electrode of the fifth transistor M5 is coupled to the light emitting control line En. The fifth transistor M5, as described above, is turned on when the light emitting control signal is not supplied from the light emitting control line En, thereby coupling (e.g., electrically coupling) the first power supply ELVDD and the first node N1 to each other.

Further, the first electrode of the sixth transistor M6 is coupled to the second electrode of the first transistor M1, and a second electrode thereof is coupled to the anode electrode of the organic light emitting diode OLED. In addition, a gate electrode of the sixth transistor M6 is coupled to the light emitting control line En. The sixth transistor M6, as described above, is turned on when the light emitting control signal is not supplied, thereby supplying the current supplied from the first transistor M1 to the organic light emitting diode OLED.

FIG. 3 is a waveform diagram showing a driving waveform supplied to a pixel shown in FIG. 2.

Referring to FIG. 3, first, the scan signal is supplied to the (n−1)-th scan line Sn-1, such that the second transistor M2 is turned on. When the second transistor M2 is turned on, the voltage of the anode electrode of the organic light emitting diode OLED is supplied to the first terminal of the storage capacitor Cst and a gate terminal of the first transistor M1. Here, the first terminal of the storage capacitor Cst and the gate terminal of the first transistor M1 are initialized by the voltage of the anode electrode of the organic light emitting diode OLED.

Then, as shown in FIG. 3, the scan signal is supplied to the n-th scan line Sn.

When the scan signal is supplied to the n-th scan line Sn, the third and fourth transistors M3 and M4 are turned on. When the third transistor M3 is turned on, the first transistor M1 is diode-connected. When the fourth transistor M4 is turned on, the data signal supplied to the data line Dm is supplied to the first node N1 through the fourth transistor M4. Here, since the gate electrode of the first transistor M1 is initialized by the voltage of the anode electrode of the organic light emitting diode OLED (that is, since a voltage of the gate electrode of the first transistor M1 is set to be lower than that of the data signal supplied to the first node N1), the first transistor M1 is turned on.

When the first transistor M1 is turned on, the data signal applied to the first node N1 is supplied to the first terminal of the storage capacitor Cst through the first and third transistors M1 and M3. Here, since the data signal is supplied to the storage capacitor Cst through the first transistor M1, which is diode-connected, the storage capacitor Cst is charged with a voltage corresponding to the data signal and a threshold voltage of the first transistor M1.

After the storage capacitor Cst is charged with the voltage corresponding to the data signal and the threshold voltage of the first transistor M1, the supply of the light emitting control signal is stopped, such that the fifth and sixth transistors M5 and M6 are turned on. When the fifth and sixth transistors M5 and M6 are turned on, a current path from the first power supply ELVDD to the organic light emitting diode OLED is formed. In this case, the first transistor M1 controls an amount of current flowing from the first power supply ELVDD to the organic light emitting diode OLED, corresponding to the voltage charged in the storage capacitor Cst.

The sub-pixel 140 according to the exemplary embodiments of the present invention described above initializes the gate electrode of the first transistor M1 according to the voltage of the anode electrode of the organic light emitting diode OLED. In this case, since a power line for supplying initialization power may be removed (i.e., no provided), a resolution, a yield, and the like, may be improved (e.g., improved as compared to an organic light emitting display device including a power line for supplying the initialization power to the sub-pixels). However, as described above, in the case in which the gate electrode of the first transistor M1 is initialized by the voltage of the anode electrode of the organic light emitting diode OLED, a non-uniform image may be displayed.

In an embodiment of the present invention, the sub-pixel 140 includes a red organic light emitting diode, a green organic light emitting diode, or a blue organic light emitting diode. The red organic light emitting diode is included in a red sub-pixel to generate red light, the green organic light emitting diode is included in a green sub-pixel to generate green light, and the blue organic light emitting diode is included in a blue sub-pixel to generate blue light.

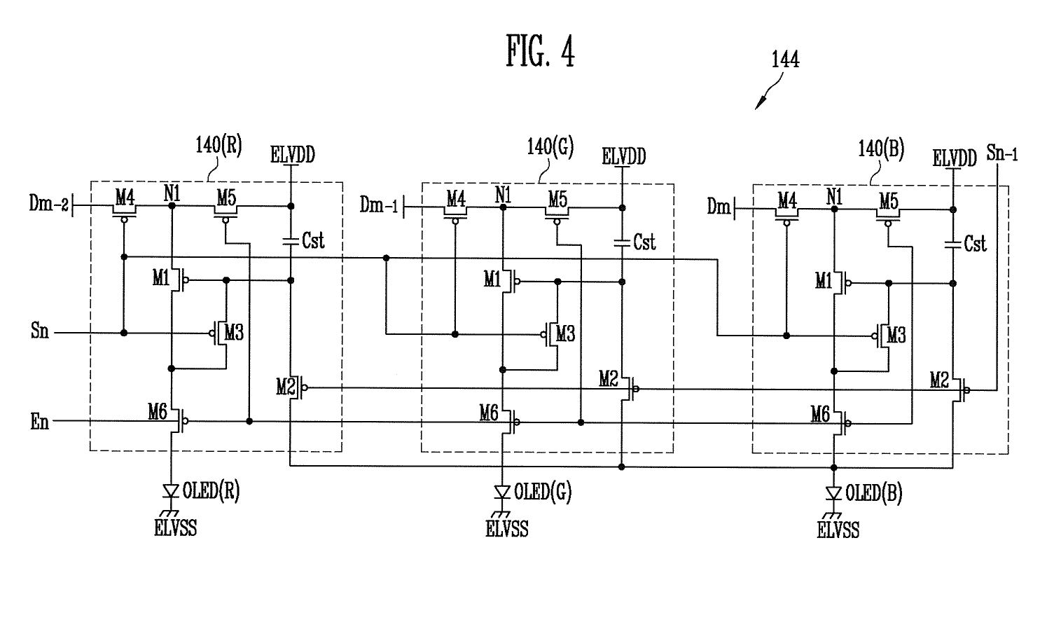

As described above, the red, green and blue organic light emitting diodes, which generate different colored lights from each other, may be made of different materials. Accordingly, voltages applied to each anode electrode may be set to be different values. Therefore, the initialization voltages of the first transistors M1 included in each of the red, green, and blue sub-pixels may be set to be different values as compared to each other, which may cause a non-uniform image to be displayed. To prevent or reduce a non-uniform image from being displayed (in addition to improving resolution and yield), a configuration of a pixel as shown in the exemplary embodiment of FIG. 4 may be used.

FIG. 4 is a diagram showing a configuration of a pixel according to an exemplary embodiment of the present invention. In describing the embodiment of present invention with reference to FIG. 4, a detailed description of the sub-pixel is given by way of reference to the sub-pixel 142 described above in connection with FIG. 2.

Referring to FIG. 4, a pixel 144 according to an exemplary embodiment of the present invention includes a red sub-pixel 140(R), a green sub-pixel 140(G), and a blue sub-pixel 140(B) that are adjacent to each other. Here, first transistors M1 included in each of the red sub-pixel 140(R), the green sub-pixel 140(G), and the blue sub-pixel 140(B) are initialized by a voltage of an anode electrode of a red organic light emitting diode OLED(R), a green organic light emitting diode OLED(G), or a blue organic light emitting diode OLED(B). For example, the first transistors M1 included in each the sub-pixels 140(R), 140(G), and 140(B) are initialized by the voltage of the anode electrode of the blue organic light emitting diode OLED(B) (e.g., as illustrated in FIG. 4).

In some embodiments, if the first transistors M1 included in each of the sub-pixels 140(R), 140(G), and 140(B) are coupled to the anode electrode of the red organic light emitting diode OLED(R) or the green organic light emitting diode OLED(G), a black brightness may increase. On the other hand, in some embodiments, if the first transistors M1 included in each of the sub-pixels 140(R), 140(G), and 140(B) are coupled to the anode electrode of the blue organic light emitting diode OLED(B), the image may be stably displayed without an increase in the black brightness.

Further, as in the embodiment of the present invention illustrated in FIG. 4, if the first transistors M1 included in each of the sub-pixels 140(R), 140(G), and 140(B) are commonly coupled to the anode electrode of the blue organic light emitting diode OLED(B), the first transistors M1 are initialized by the same voltage, thereby displaying a uniform image.

Although the embodiment where the sub-pixels 140(R), 140(G), and 140(B), included in the same pixel 144, are coupled to the anode electrode of the blue organic light emitting diode OLED(B) positioned in the pixel 144 is shown in FIG. 4, the present invention is not limited thereto. For example, the sub-pixels 140(R), 140(G), and 140(B) may also be coupled to an anode electrode of any one of a plurality of blue organic light emitting diodes included in the pixel unit 130.

As set forth above, with the organic light emitting display device and the method of driving the same according to the exemplary embodiment of the present invention, the driving transistors included in each of the sub-pixels are initialized by the voltage applied to the anode electrode of the red, green, or blue organic light emitting diodes. In this case, the power line for initialization power may be removed, thereby making it possible to increase the resolution and the yield.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

what is claimed is:

1. An organic light emitting display device comprising:
red sub-pixels, each comprising a red organic light emitting diode and a driving transistor;
green sub-pixels, each comprising a green organic light emitting diode and a driving transistor; and
blue sub-pixels, each comprising a blue organic light emitting diode and a driving transistor,
wherein the driving transistors of the red, green, and blue sub-pixels are configured to be initialized by a voltage applied to an anode electrode of the red, green, or blue organic light emitting diodes.

2. The organic light emitting display device according to claim 1, wherein the driving transistors are configured to be initialized by the voltage applied to the anode electrode of the blue organic light emitting diode.

3. The organic light emitting display device according to claim 1, wherein the red, green, and blue sub-pixels that are adjacent to each other form one of the plurality of pixels, and
wherein the driving transistors in a same one of the pixels are configured to be initialized by the voltage applied to the anode electrode of the red, green, or blue organic light emitting diodes in the same one of the pixels.

4. The organic light emitting display device according to claim 3, wherein the driving transistors in the same one of the pixels are configured to be initialized by the voltage applied to the anode electrode of the blue organic light emitting diode in the same one of the pixels.

5. The organic light emitting display device according to claim 4, wherein each of the red, green, and blue sub-pixels that is positioned at an i-th (i being a natural number) horizontal line further comprises a second transistor coupled between a gate electrode of the driving transistor and the anode electrode of the blue organic light emitting diode in the same one of the pixels, the second transistor being configured to be turned on when a scan signal is supplied to an (i×1)-th scan line.

6. The organic light emitting display device according to claim 5, wherein each of the red, green, and blue sub-pixels that is positioned at the i-th (i being a natural number) horizontal line further comprises:
a third transistor coupled between the gate electrode of the driving transistor and a second electrode of the driving transistor, the third electrode being configured to be turned on when the scan signal is supplied to an i-th scan line;
a fourth transistor coupled between a first electrode of the driving transistor and a data line, the fourth transistor being configured to be turned on when the scan signal is supplied to the i-th scan line;
a fifth transistor coupled between the first electrode of the driving transistor and a first power supply, the fifth transistor being configured to be turned off when a light emitting control signal is supplied to an i-th light emitting control line;
a sixth transistor coupled between the second electrode of the driving transistor and an anode electrode of an organic light emitting diode included therein, the sixth transistor being configured to be turned off when the light emitting control signal is supplied to the i-th light emitting control line; and
a storage capacitor coupled between the gate electrode of the driving transistor and the first power supply.

7. The organic light emitting display device according to claim 6, wherein the light emitting control signal is configured to be supplied to the i-th light emitting control line such that it is overlapped with the scan signals supplied to the (i-1)-th scan line and the i-th scan line.

8. A method of driving an organic light emitting display device, the method comprising:
initializing a gate electrode of a driving transistor included in each of a plurality of sub-pixels;
storing a voltage corresponding to a data signal in each of the sub-pixels; and
generating light corresponding to the stored voltage of the data signal in each of the sub-pixels,
wherein each of the sub-pixels is initialized by a voltage of an anode electrode of a red organic light emitting diode, a green organic light emitting diode, or a blue organic light emitting diode.

9. The driving method according to claim 8, wherein the sub-pixels are initialized by the voltage of the anode electrode of the blue organic light emitting diode.

10. The driving method according to claim 8,
wherein each of the sub-pixels comprises either a red sub-pixel, a blue sub-pixel, or a green sub-pixel,
wherein one of the red sub-pixels, one of the blue sub-pixels, and one of the green sub-pixels that are all arranged adjacent to each other comprise one pixel of a plurality of pixels, and
wherein the red sub-pixel, the blue sub-pixel, and the green sub-pixel of a same one of the pixels are all initialized by the voltage of the anode electrode of the red organic light emitting diode, the green organic light emitting diode, or the blue organic light emitting diode of the same one of the pixels.

11. The driving method according to claim 10,
wherein the red sub-pixel, the blue sub-pixel, and the green sub-pixel of the same one of the pixels are initiated by the voltage of the anode electrode of the blue organic light emitting diode of the blue sub-pixel of the same one of the pixels.
